(19) United States
(12) Patent Application Publication
(10) Pub. No.: US 2019/0079121 A1
(43) Pub. Date: Mar. 14, 2019

(54) ESTIMATING A CURRENT IN AN SMPS

(71) Applicant: Telefonaktiebolaget LM Ericsson (publ), Stockholm (SE)

(72) Inventors: Andreas Larsson, Kalmar (SE); Ulf Borssén, Kalmar (SE); Magnus Karlsson, Oskarshamn (SE)

(73) Assignee: Telefonaktiebolaget LM Ericsson (publ), Stockholm, SE (SE)

(21) Appl. No.: 15/769,163

(22) PCT Filed: Oct. 20, 2015
(86) PCT No.: PCT/SE2015/051116

§ 371 Date: Apr. 18, 2018

(51) Int. Cl. G01R 19/32; H02M 3/156; H02M 1/32

(52) U.S. Cl. CPC G01R 19/32; H02M 2001/0009; H02M 1/32; H02M 3/156

(57) ABSTRACT

The present disclosure relates to a method for estimating a current in a Switched-Mode Power Supply (SMPS). The method comprises receiving a first sensor signal comprising a value of a measured voltage over a resistive element in the SMPS. The method also comprises receiving a second sensor signal comprising a value of a measured monitored temperature in the SMPS. The method also comprises calculating the current in the SMPS based on the measured voltage, the measured monitored temperature, and a predetermined temperature difference between a real temperature of the resistive element and the monitored temperature.

### TECHNICAL FIELD

The present disclosure relates to estimation of the current in a Switched-Mode Power Supply (SMPS).

### BACKGROUND

A common method for measuring the current in an SMPS is to measure the voltage across a resistive element, e.g. a resistance of an inductor or a source-drain resistance of a Metal-Oxide-Semiconductor Field-Effect Transistor (MOSFET). Since the resistance, e.g. of a copper conductor, typically varies with temperature, a compensation for temperature is applied to the measured voltage in order to achieve an acceptable accuracy of the measurement.

The voltage across a resistive element due to a current passing through is given by equation 1:

V_{ISENSE}=I·DCR(1+TC(T−25)) (1)

Where I is the current, DCR is the direct current (DC) resistance at 25° C., TC is the temperature coefficient of the resistance and T the temperature of the resistive element.

The measured voltage is translated to a value of the current by using a gain value GAIN that should ideally equal the actual DCR value. The common way is to compensate the GAIN value based on an assumed temperature coefficient TEMPCO and a monitored temperature T_{MON} in accordance with equation 2:

$${I}_{READ} = \frac{{V}_{ISENSE}}{GAIN ( 1 + TEMPCO ( {T}_{MON} - 25 ) )} + OFFSET = \frac{I \cdot DCR ( 1 + TC ( T - 25 ) )}{GAIN ( 1 + TEMPCO ( {T}_{MON} - 25 ) )} + OFFSET \qquad ( 2 )$$

wherein OFFSET is an offset due to circuit design which may be zero in ideal cases or may be small enough to be disregarded.

### SUMMARY

If GAIN is close to DCR, the calculated current value will correspond well with the actual current if the measured temperature T_{MON} equals the actual temperature T of the resistive element. However, if the measured temperature T_{MON} does not equal the actual temperature T of the resistive element, the calculated current may differ substantially from the actual current. In many cases it is difficult to measure the temperature of the actual resistive element. It may e.g. be difficult to fit an external temperature sensor directly onto the resistive element, why the measured temperature T_{MON} may be measured nearby the resistive element rather than directly on it. The temperature sensor is then instead placed at a distance from the resistive element (due space restrictions or to save cost by using already available sensors) and there will be a mismatch between T_{MON} and T. The mismatch will depend on the thermal conditions which in turn depend on operating parameters such as input and output voltage levels, output current level, as well as temperature and air flow (e.g. forced ventilation/cooling or natural airflow if the SMPS is mounted outdoors).

Assuming GAIN=DCR, TEMPCO=TC=3900 ppm/° C. (which is typical for copper) and excluding the offset, the percentage error of actual current will be in accordance with equation 3:

$$e = \frac{{I}_{READ} - I}{I} = \frac{1 + 0.0039 ( T - 25 )}{1 + 0.0039 ( {T}_{MON} - 25 )} - 1 \qquad ( 3 )$$

Herein a time difference ΔT=T_{MON}−T is introduced to obtain a more correct value of the current through the SMPS. With e.g. high current SMPS designs, the ΔT can be a quite large negative number due to the high current through the resistive element, thus giving a large error in monitored temperature.

By e.g. adjusting TEMPCO in equation 2 to not equal TC, it is possible to reduce the ΔT for a certain operating area, e.g. for negative ΔT values, but not for a wider range of ΔT values.

In accordance with the present disclosure, a control unit is introduced as an observer that monitors operating conditions and makes temperature compensation based on ΔT for actual conditions. Compared to the solutions described above this may give a more accurate temperature compensation across a wider range of operating conditions.

The control unit may be implemented in the SMPS product itself, or in an external system host communicating with the SMPS product.

The data needed may be collected by Design of Experiment (DOE), measuring ΔT when operating the SMPS across a wide range of operating conditions. Least square regression may then used to calculate the coefficients in a model.

According to an aspect of the present disclosure, there is provided a method for estimating a current in a Switched-Mode Power Supply (SMPS). The method comprises receiving a first sensor signal comprising a value of a measured voltage over a resistive element in the SMPS. The method also comprises receiving a second sensor signal comprising a value of a measured monitored temperature in the SMPS. The method also comprises calculating the current in the SMPS based on the measured voltage, the measured monitored temperature, and a predetermined temperature difference between a real temperature of the resistive element and the monitored temperature.

According to another aspect of the present disclosure, there is provided a control arrangement comprising a control unit, for estimating a current in an SMPS. The control arrangement comprises processor circuitry, and storage storing instructions executable by said processor circuitry whereby said control arrangement is operative to receive a first sensor signal comprising a value of a measured voltage over a resistive element in the SMPS. The control arrangement is also operative to receive a second sensor signal comprising a value of a measured monitored temperature in the SMPS. The control arrangement is also operative to calculate the current in the SMPS based on the measured voltage, the measured monitored temperature, and a predetermined temperature difference between a real temperature of the resistive element and the monitored temperature.

According to another aspect of the present disclosure, there is provided a method for experimentally determining constant values of coefficients and optional constant for a polynomial function describing a temperature difference between a real temperature of a resistive element and a monitored temperature in an SMPS. The method comprises measuring the real temperature. The method also comprises measuring the monitored temperature. The method also comprises determining the real temperature difference as the difference between the measured real and monitored temperatures. The method also comprises measuring values of physical parameters affecting the temperature difference. The method also comprises performing iterative experimentation for obtaining the polynomial function and determining the constant values of coefficients and optional constant of said polynomial function such that the temperature difference given by the polynomial function converges with the determined real temperature difference.

According to another aspect of the present disclosure, there is provided a control unit for experimentally determining constant values of coefficients and optional constant for a polynomial function describing a temperature difference between a real temperature of a resistive element and a monitored temperature in an SMPS. The control unit comprises processor circuitry, and storage storing instructions executable by said processor circuitry whereby said control unit is operative to measure the real temperature. The control unit is also operative to measure the monitored temperature. The control unit is also operative to determine the real temperature difference as the difference between the measured real and monitored temperatures. The control unit is also operative to measure values of physical parameters affecting the temperature difference. The control unit is also operative to perform iterative experimentation for obtaining the polynomial function and determining the constant values of coefficients and optional constant of said polynomial function such that the temperature difference given by the polynomial function converges with the determined real temperature difference.

According to another aspect of the present disclosure, there is provided a method performed by a control unit for determining a temperature difference between a real temperature of a resistive element and a monitored temperature in an SMPS. The method comprises obtaining constant values of coefficients and optional constant of a polynomial function describing said temperature difference. The method also comprises obtaining parameter values of variable physical parameters of said polynomial function, at least some of the parameter values being obtained by receiving sensor measurement signals. The method also comprises calculating the temperature difference by solving the polynomial function having the obtained constant values and the obtained parameter values. The method also comprises outputting a signal comprising the calculated temperature difference to a controller of the SMPS.

According to another aspect of the present disclosure, there is provided a control unit for determining a temperature difference between a real temperature of a resistive element and a monitored temperature in an SMPS. The control unit comprises processor circuitry, and storage storing instructions executable by said processor circuitry whereby said control unit is operative to obtain constant values of coefficients and optional constant of a polynomial function describing said temperature difference. The control unit is also operative to obtain parameter values of variable physical parameters of said polynomial function, at least some of the parameter values being obtained by receiving sensor measurement signals. The control unit is also operative to calculate the temperature difference by solving the polynomial function having the obtained constant values and the obtained parameter values. The control unit is also operative to output a signal comprising the calculated temperature difference to a controller in the SMPS.

According to another aspect of the present disclosure, there is provided a computer program product comprising computer-executable components for causing a control unit to perform an embodiment of a method of the present disclosure when the computer-executable components are run on processor circuitry comprised in the control unit.

According to another aspect of the present disclosure, there is provided a computer program for estimating a current in an SMPS. The computer program comprises computer program code which is able to, when run on processor circuitry of a control unit, cause the control unit to receive a first sensor signal comprising a value of a measured voltage over a resistive element in the SMPS. The code is also able to cause the control unit to receive a second sensor signal comprising a value of a measured monitored temperature in the SMPS. The code is also able to cause the control unit to calculate the current in the SMPS based on the measured voltage, the measured monitored temperature, and a predetermined temperature difference between a real temperature of the resistive element and the monitored temperature.

According to another aspect of the present disclosure, there is provided a computer program for experimentally determining constant values of coefficients and optional constant for a polynomial function describing a temperature difference between a real temperature of a resistive element and a monitored temperature in an SMPS. The computer program comprises computer program code which is able to, when run on processor circuitry of a control unit, cause the control unit to measure the real temperature. The code is also able to cause the control unit to measure the monitored temperature. The code is also able to cause the control unit to determine the real temperature difference as the difference between the measured real and monitored temperatures. The code is also able to cause the control unit to measure values of physical parameters affecting the temperature difference. The code is also able to cause the control unit to perform iterative experimentation for obtaining the polynomial function and determining the constant values of coefficients and optional constant of said polynomial function such that the temperature difference given by the polynomial function converges with the determined real temperature difference.

According to another aspect of the present disclosure, there is provided a computer program for determining a temperature difference between a real temperature of a resistive element and a monitored temperature in an SMPS. The computer program comprises computer program code which is able to, when run on processor circuitry of a control unit, cause the control unit to obtain constant values of coefficients and optional constant of a polynomial function describing said temperature difference. The code is also able to cause the control unit to obtain parameter values of variable physical parameters of said polynomial function, at least some of the parameter values being obtained by receiving sensor measurement signals. The code is also able to cause the control unit to calculate the temperature difference by solving the polynomial function having the obtained constant values and the obtained parameter values. The code is also able to cause the control unit to output a signal comprising the calculated temperature difference to a controller in the SMPS.

According to another aspect of the present disclosure, there is provided a computer program product comprising an embodiment of a computer program of the present disclosure and a computer readable means on which the computer program is stored.

It is to be noted that any feature of any of the aspects may be applied to any other aspect, wherever appropriate. Likewise, any advantage of any of the aspects may apply to any of the other aspects. Other objectives, features and advantages of the enclosed embodiments will be apparent from the following detailed disclosure, from the attached dependent claims as well as from the drawings.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. The use of “first”, “second” etc. for different features/components of the present disclosure are only intended to distinguish the features/components from other similar features/components and not to impart any order or hierarchy to the features/components.

### BRIEF DESCRIPTION OF THE DRAWINGS

Embodiments will be described, by way of example, with reference to the accompanying drawings, in which:

FIG. 1 is a schematic block diagram of an embodiment of a control unit associated with an SMPS in accordance with the present disclosure.

FIG. 2 is a schematic illustration of an embodiment of a computer program product in accordance with the present disclosure.

FIG. 3a is a schematic flow chart of an embodiment of a method of the present disclosure.

FIG. 3b is a schematic functional block diagram of an embodiment of a control arrangement of the present disclosure.

FIG. 4a is a schematic flow chart of another embodiment of a method of the present disclosure.

FIG. 4b is a schematic functional block diagram of an embodiment of a control unit of the present disclosure.

FIG. 5a is a schematic flow chart of another embodiment of a method of the present disclosure.

FIG. 5b is a schematic functional block diagram of an embodiment of a control unit of the present disclosure.

### DETAILED DESCRIPTION

Embodiments will now be described more fully hereinafter with reference to the accompanying drawings, in which certain embodiments are shown. However, other embodiments in many different forms are possible within the scope of the present disclosure. Rather, the following embodiments are provided by way of example so that this disclosure will be thorough and complete, and will fully convey the scope of the disclosure to those skilled in the art. Like numbers refer to like elements throughout the description.

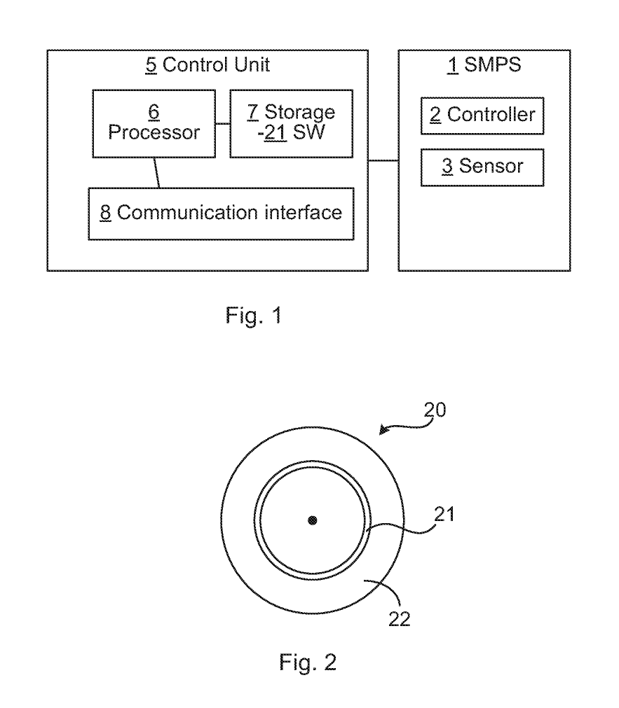

FIG. 1 illustrates an SMPS 1 associated with a control unit 5. The control unit 5 may be comprised in the SMPS or may be external to the SMPS 1, as in the figure. An external control unit 5 may for example be comprised in a Board Power Manager (BPM). The control unit 5 is part of a control arrangement for the SMPS, which control arrangement may also comprise the controller 2 in the SMPS, especially if the control unit 5 is external to the SMPS. If the control unit 5 is internal, i.e. comprised in the SMPS, the controller 2 may be comprised in or merged with the control unit 5. The SMPS 1 also comprises at least one sensor, such as a temperature sensor for measuring the monitored temperature T_{MON} and/or a voltage sensor for measuring the voltage V_{ISENSE}, which at least one sensor may output measured values to the control unit 5.

The control unit 5 comprises processor circuitry 6 e.g. a central processing unit (CPU). The processor circuitry 6 may comprise one or a plurality of processing units in the form of microprocessor(s). However, other suitable devices with computing capabilities could be comprised in the processor circuitry 6, e.g. an application specific integrated circuit (ASIC), a field programmable gate array (FPGA) or a complex programmable logic device (CPLD). The processor circuitry 6 is configured to run one or several computer program(s) or software (SW) 21 (see also FIG. 2) stored in a storage 7 of one or several storage unit(s) e.g. a memory. The storage unit is regarded as a computer readable means 22 (see FIG. 2) as discussed herein and may e.g. be in the form of a Random Access Memory (RAM), a Flash memory or other solid state memory, or a hard disk, or be a combination thereof. The processor circuitry 6 may also be configured to store data in the storage 7, as needed. The control unit 5 may also comprise a communication interface for communication with e.g. sensors and/or other parts of the SMPS 1 outside of the control unit 5.

According to an aspect of the present disclosure, there is provided a control arrangement comprising a control unit 5, for estimating a current in an SMPS 1. The control arrangement comprises processor circuitry 6, and storage 7 storing instructions 21 executable by said processor circuitry whereby said control arrangement is operative to receive a first sensor signal comprising a value of a measured voltage V_{ISENSE} over a resistive element in the SMPS. The control arrangement is also operative to receive a second sensor signal comprising a value of a measured monitored temperature T_{MON} in the SMPS. The control arrangement is also operative to calculate the current in the SMPS based on the measured voltage V_{ISENSE}, the measured monitored temperature T_{MON}, and a predetermined temperature difference ΔT between a real temperature T of the resistive element and the monitored temperature T_{MON}.

In case the the control unit is comprised in the SMPS, the control arrangement may essentially consist of the control unit. The control arrangement or control unit 5 may then calculate I_{READ} taking ΔT into account in accordance with equation 4:

$${I}_{READ} = \frac{{V}_{ISENSE}}{GAIN ( 1 + TEMPCO ( {T}_{MON} - Δ T - 25 ) )} + OFFSET \qquad ( 4 )$$

wherein
I_{READ} is the current calculated in the SMPS,
V_{ISENSE} is the measured voltage,
GAIN is a gain value related to the resistance of the resistive element at 25° C.,
T_{MON} is the monitored temperature,
TEMPCO is a temperature coefficient,
ΔT is the predetermined temperature difference, and
OFFSET is an offset due to circuit design.

ΔT may be calculated internally, based on monitored operating conditions, using a model of ΔT. For an internal control unit 5, the airflow may not be monitored and may need to be preset.

However, if the control unit is external to the SMPS, the control arrangement may in addition to the control unit comprise an SMPS internal controller 2. The internal controller may in that cased calculate I_{READ} in accordance with equation 2 (as above):

$${I}_{READ} = \frac{{V}_{ISENSE}}{GAIN ( 1 + TEMPCO ( {T}_{MON} - 25 ) )} + OFFSET \qquad ( 2 )$$

while the external control unit 5 then calculate a corrected I_{READ} taking ΔT into account in accordance with equation 5:

$${I}_{READ \_ CORRECTED} = ( {I}_{READ} - OFFSET ) \cdot \frac{1 + TEMPCO ( {T}_{MON} - 25 )}{1 + TEMPCO ( {T}_{MON} - Δ T - 25 )} + OFFSET \qquad ( 5 )$$

wherein
I_{READ}_{_}_{CORRECTED} is the current calculated in the external control unit,
I_{READ} is the current calculated in the SMPS and signaled to the control unit,
T_{MON} is the monitored temperature,
TEMPCO is a temperature coefficient,
ΔT is the predetermined temperature difference, and
OFFSET is an offset due to circuit design.

The I_{READ} parameter in this case is assumed to be calculated in the SMPS 1 according to equation 2, i.e. the parameters T_{MON}, TEMPCO and OFFSET in equation 5 are typically the same as was used in the SMPS when calculating I_{READ}. ΔT may be calculated in the external control unit 5, based on monitored operating conditions reported by the SMPS 1 and/or other sensors in the system, using a model of ΔT.

In determining a model for the estimation of ΔT a polynomial function may be obtained from iterative experimentation e.g. so called Design of Experiment (DOE) using e.g. an approximation method such as least square regression.

An example of a first order polynomial function of ΔT may be in accordance with equation 6:

ΔT=b₁V₁+b₂V_{O}+b₃I_{O}+b₄v+T_{MON}+b₆ (6)

wherein the variables are input voltage V_{I}, output voltage V_{O}, output current I_{O} and measured temperature T_{MON} and are typically monitored continuously by the controller 2 or internal control unit 5 of the SMPS 1 itself by means of sensors 3. The airflow v may have to be known or provided through external sensor/source or be preprogramed. Any variables may be used which are available (measureable or estimatable) and may influence ΔT. For example, T_{MON} may be used in addition to or instead of any of the variables in equation 6.

The coefficients b1-b6 may be decided by DOE. Depending on the desired model accuracy, and data available, one may choose to exclude one or more of the parameters in equation 6. Further, equation 6 is not limited to a first order model but may be any polynomial function of the included parameters (e.g. see equation 7, below, where dependence between parameters X1 and X2 is included).

A definition of Design of Experiment (this is a standard approach in statistics) is to by using a minimal number of measurements, varying one variable Xᵢ at the time and keep the others constant, and use least square to minimize errors in the linear model, with cross-dependencies, by adjusting the coefficients bᵢ. In equation 4 an example with two independent variables is shown in equation 7:

Y=b₁X₁+b₂X₂+b₃X₁X₂ (7)

The measurements may be done at the extreme values of each variable (denoted with value −1 and 1, covering all the worst case corners as described in the table below.

| X₁ | X₂ | X₁*X₂ |
|---|---|---|
| −1 | −1 | 1 |
| −1 | 1 | −1 |
| 1 | −1 | −1 |
| 1 | 1 | 1 |

According to another aspect of the present disclosure, there is provided a control control unit 5 for experimentally determining constant values of coefficients b1-5 and optional constant b6 for a polynomial function describing a temperature difference ΔT between a real temperature T of a resistive element and a monitored temperature T_{MON} in an SMPS 1. The control unit comprises processor circuitry 6, and storage 7 storing instructions 21 executable by said processor circuitry whereby said control unit is operative to measure the real temperature T. The control unit is also operative to measure the monitored temperature T_{MON}. The control unit is also operative to determine the real temperature difference ΔT as the difference between the measured real and monitored temperatures. The control unit is also operative to measure values of physical parameters affecting the temperature difference ΔT. The control unit is also operative to perform iterative experimentation for obtaining the polynomial function and determining the constant values of coefficients b1-5 and optional constant b6 of said polynomial function such that the temperature difference ΔT given by the polynomial function converges with the determined real temperature difference.

When the polynomial function is known (has been determined), it may be used to estimate the temperature difference ΔT which may then be used by the control arrangement for estimating the current through the SMPS as discussed herein.

According to another aspect of the present disclosure, there is provided a control unit 5 for determining a temperature difference ΔT between a real temperature T of a resistive element and a monitored temperature T_{MON} in an SMPS. The control unit comprises processor circuitry 6, and storage 7 storing instructions 21 executable by said processor circuitry whereby said control unit is operative to obtain constant values of coefficients b₁₋₅ and optional constant b₆ of a polynomial function describing said temperature difference ΔT. The control unit is also operative to obtain parameter values of variable physical parameters of said polynomial function, at least some of the parameter values being obtained by receiving sensor measurement signals. The control unit is also operative to calculate the temperature difference ΔT by solving the polynomial function having the obtained constant values and the obtained parameter values. The control unit is also operative to output a signal comprising the calculated temperature difference ΔT to a controller in the SMPS.

FIG. 2 illustrates an embodiment of a computer program product 20. The computer program product 20 comprises a computer readable (e.g. non-volatile and/or non-transitory) medium 22 comprising software/computer program 21 in the form of computer-executable components. The computer program 21 may be configured to cause a control arrangement or control unit 5, e.g. as discussed herein, to perform an embodiment of a method of the present disclosure. The computer program may be run on the processor circuitry 6 of the a control arrangement or control unit 5 for causing it to perform the method. The computer program product 20 may e.g. be comprised in a storage unit or memory 7 comprised in the a control arrangement or control unit 5 and associated with the processor circuitry 6. Alternatively, the computer program product 20 may be, or be part of, a separate, e.g. mobile, storage means/medium, such as a computer readable disc, e.g. CD or DVD or hard disc/drive, or a solid state storage medium, e.g. a RAM or Flash memory. Further examples of the storage medium can include, but are not limited to, any type of disk including floppy disks, optical discs, DVD, CD-ROMs, microdrive, and magneto-optical disks, ROMs, RAMs, EPROMs, EEPROMs, DRAMs, VRAMs, flash memory devices, magnetic or optical cards, nanosystems (including molecular memory ICs), or any type of media or device suitable for storing instructions and/or data. Embodiments of the present disclosure may be conveniently implemented using one or more conventional general purpose or specialized digital computer, computing device, machine, or microprocessor, including one or more processors, memory and/or computer readable storage media programmed according to the teachings of the present disclosure. Appropriate software coding can readily be prepared by skilled programmers based on the teachings of the present disclosure, as will be apparent to those skilled in the software art.

According to an aspect of the present disclosure, there is provided a computer program product 20 comprising computer-executable components 21 for causing a control arrangement or control unit 5 to perform an embodiment of a method of the present disclosure when the computer-executable components are run on processor circuitry 6 comprised in the control arrangement or control unit.

According to another aspect of the present disclosure, there is provided a computer program 21 for estimating a current in an SMPS 1. The computer program comprises computer program code which is able to, when run on processor circuitry 6 of a control arrangement or control unit 5, cause the control arrangement or control unit to receive a first sensor signal comprising a value of a measured voltage V_{ISENSE} over a resistive element in the SMPS; receive a second sensor signal comprising a value of a measured monitored temperature T_{MON} in the SMPS; and calculate the current in the SMPS based on the measured voltage V_{ISENSE}, the measured monitored temperature T_{MON}, and a predetermined temperature difference ΔT between a real temperature T of the resistive element and the monitored temperature T_{MON}.

According to another aspect of the present disclosure, there is provided a computer program 21 for experimentally determining constant values of coefficients b₁₋₅ and optional constant b₆ for a polynomial function describing a temperature difference ΔT between a real temperature T of a resistive element and a monitored temperature T_{MON} in an SMPS 1. The computer program comprises computer program code which is able to, when run on processor circuitry 6 of a control unit 5, cause the control unit to measure the real temperature T. The code is also able to cause the control unit to measure the monitored temperature T_{MON}. The code is also able to cause the control unit to determine the real temperature difference ΔT as the difference between the measured real and monitored temperatures. The code is also able to cause the control unit to measure values of physical parameters affecting the temperature difference ΔT. The code is also able to cause the control unit to perform iterative experimentation for obtaining the polynomial function and determining the constant values of coefficients b₁₋₅ and optional constant b₆ of said polynomial function such that the temperature difference ΔT given by the polynomial function converges with the determined real temperature difference.

According to another aspect of the present disclosure, there is provided a computer program 21 for determining a temperature difference ΔT between a real temperature T of a resistive element and a monitored temperature T_{MON} in an SMPS 1. The computer program comprises computer program code which is able to, when run on processor circuitry 6 of a control unit 5, cause the control unit to obtain constant values of coefficients b₁₋₅ and optional constant b₆ of a polynomial function describing said temperature difference ΔT. The code is also able to cause the control unit to obtain parameter values of variable physical parameters of said polynomial function, at least some of the parameter values being obtained by receiving sensor measurement signals. The code is also able to cause the control unit to calculate the temperature difference ΔT by solving the polynomial function having the obtained constant values and the obtained parameter values. The code is also able to cause the control unit to output a signal comprising the calculated temperature difference ΔT to a controller in the SMPS.

According to another aspect of the present disclosure, there is provided a computer program product 20 comprising an embodiment of a computer program 21 of the present disclosure and a computer readable means 22 on which the computer program is stored.

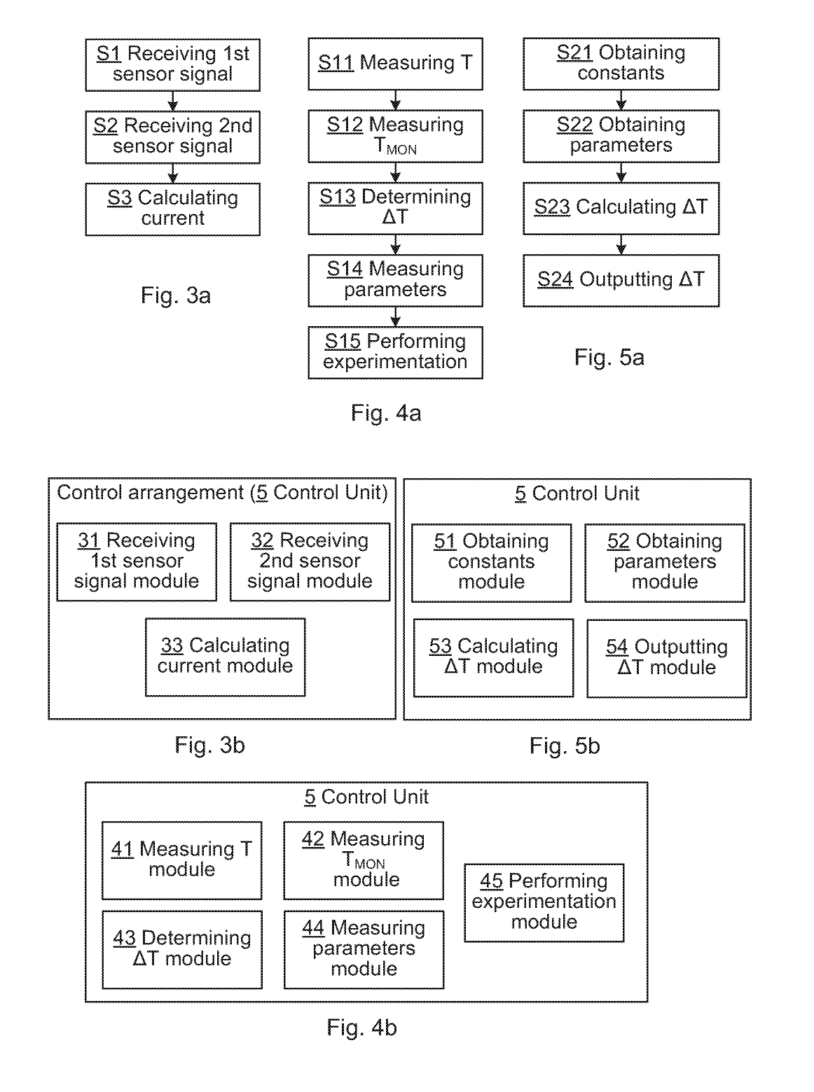

FIG. 3a is a schematic flow chart of an embodiment of a method for estimating a current in an SMPS 1. The method may be performed by the control unit 5. However, as discussed above, if the control unit 5 is external to the SMPS, the method may be performed in a control arrangement comprising the control unit 5 as well as parts e.g. the controller 2 in the SMPS. A first sensor signal comprising a value of a measured voltage V_{ISENSE} over a resistive element in the SMPS is received S1, e.g. from a sensor 3 in the SMPS. Also, before or after receiving S1 the first sensor signal, a second sensor signal comprising a value of a measured monitored temperature T_{MON} in the SMPS is received S2, e.g. from a sensor 3 in the SMPS. Then, the current in the SMPS is calculated S3 based on the measured voltage V_{ISENSE}, the measured monitored temperature T_{MON}, and a predetermined temperature difference ΔT between a real temperature T of the resistive element and the monitored temperature T_{MON}. As discussed herein, in some embodiments, the method is performed by a control unit 5 comprised in the SMPS, while in other embodiments, the method is performed at least partly by a control unit 5 which is external to the SMPS 1.

FIG. 3b is a schematic block diagram functionally illustrating an embodiment of a control arrangement comprising a control unit 5 as discussed herein. As previously mentioned, the processor circuitry 6 may run software 21 for enabling the control arrangement to perform an embodiment of a method of the present disclosure, whereby functional modules may be formed in the control arrangement e.g. in the processor circuitry 6 for performing the different steps of the method. These modules are schematically illustrated as blocks within the control arrangement. Thus, the control arrangement comprises a receiving first sensor signal module 31 for receiving S1 a first sensor signal comprising a value of a measured voltage V_{ISENSE} over a resistive element in the SMPS. The control arrangement also comprises a receiving second sensor signal module 32 for receiving S2 a second sensor signal comprising a value of a measured monitored temperature T_{MON} in the SMPS. The control arrangement also comprises a calculating current module 33 for calculating S3 the current in the SMPS based on the measured voltage V_{ISENSE}, the measured monitored temperature T_{MON}, and a predetermined temperature difference ΔT between a real temperature T of the resistive element and the monitored temperature T_{MON}. Alternatively, the modules 31-33 may be formed by hardware, or by a combination of software and hardware.

According to an aspect of the present disclosure, there is provided a control arrangement for estimating a current in an SMPS. The control arrangement comprises means 31 for receiving S1 a first sensor signal comprising a value of a measured voltage V_{ISENSE} over a resistive element in the SMPS. The control arrangement also comprises means 32 for receiving S2 a second sensor signal comprising a value of a measured monitored temperature T_{MON} in the SMPS. The control arrangement also comprises means 33 for calculating S3 the current in the SMPS based on the measured voltage V_{ISENSE}, the measured monitored temperature T_{MON}, and a predetermined temperature difference ΔT between a real temperature T of the resistive element and the monitored temperature T_{MON}.

FIG. 4a is a schematic flow chart of an embodiment of a method for experimentally determining constant values of coefficients b₁₋₅ and optional constant b₆ for a polynomial function describing a temperature difference ΔT between a real temperature T of a resistive element and a monitored temperature T_{MON} in an SMPS 1. A control unit 5 (the same as or different from the control unit 5 discussed in relation to the method for estimating a current) measures S11 the real temperature T. The control unit 5 also measures S12 the monitored temperature T_{MON}. Then, the control unit 5 determines S13 the real temperature difference ΔT as the difference between the measured real and monitored temperatures. The control unit also measures S14 values of physical parameters affecting the temperature difference ΔT. Based on these measurements, the control unit 5 performs S15 iterative experimentation for obtaining the polynomial function and determining the constant values of coefficients b₁₋₅ and optional constant b₆ of said polynomial function such that the temperature difference ΔT given by the polynomial function converges with the determined real temperature difference. In some embodiments, the iterative experimentation comprises DOE techniques comprising an approximation method e.g. least square regression, as discussed above.

FIG. 4b is a schematic block diagram functionally illustrating an embodiment of a control unit 5 as discussed herein. As previously mentioned, the processor circuitry 6 may run software 21 for enabling the control unit to perform an embodiment of a method of the present disclosure, whereby functional modules may be formed in the control unit e.g. in the processor circuitry 6 for performing the different steps of the method. These modules are schematically illustrated as blocks within the control unit. Thus, the control unit comprises a measuring T module 41 for measuring S11 the real temperature T. The control unit also comprises a measuring T_{MON} module 42 for measuring S12 the monitored temperature T_{MON}. The control unit also comprises a determining ΔT module 43 for determining S13 the real temperature difference ΔT as the difference between the measured real and monitored temperatures. The control unit also comprises a measuring parameters module 44 for measuring S14 values of physical parameters affecting the temperature difference ΔT. The control unit also comprises a performing experimentation module 45 for performing S15 iterative experimentation for obtaining the polynomial function and determining the constant values of coefficients b₁₋₅ and optional constant b₆ of said polynomial function such that the temperature difference ΔT given by the polynomial function converges with the determined real temperature difference Alternatively, the modules 41-45 may be formed by hardware, or by a combination of software and hardware.

According to an aspect of the present disclosure, there is provided a control unit 5 for experimentally determining constant values of coefficients b₁₋₅ and optional constant b₆ for a polynomial function describing a temperature difference ΔT between a real temperature T of a resistive element and a monitored temperature T_{MON} in an SMPS 1. The control unit comprises means 41 for measuring S11 the real temperature T. The control unit also comprises means 42 for measuring S12 the monitored temperature T_{MON}. The control unit also comprises means 43 for determining S13 the real temperature difference ΔT as the difference between the measured real and monitored temperatures. The control unit also comprises means 44 for measuring S14 values of physical parameters affecting the temperature difference ΔT. The control unit also comprises means 45 for performing S15 iterative experimentation for obtaining the polynomial function and determining the constant values of coefficients b₁₋₅ and optional constant b₆ of said polynomial function such that the temperature difference ΔT given by the polynomial function converges with the determined real temperature difference.

FIG. 5a is a schematic flow chart of an embodiment of a method for determining a temperature difference ΔT between a real temperature T of a resistive element and a monitored temperature T_{MON} in an SMPS 1. Constant values of coefficients b₁₋₅ and optional constant b₆ of a polynomial function describing said temperature difference ΔT are obtained S21, e.g. from a storage 7 in which they have been stored following the method of FIG. 4a or received from outside of a control unit performing the method of FIG. 5a. Parameter values of variable physical parameters of said polynomial function are obtained S22, at least some of the parameter values being obtained by receiving sensor measurement signals, e.g. from sensors 3 in the SMPS. The temperature difference ΔT is then calculated S23 by solving the polynomial function having the obtained constant values and the obtained parameter values (i.e. with the values inserted in the polynomial function). A signal comprising the calculated temperature difference ΔT is then outputted S24 to a controller 2 of the SMPS.

FIG. 5b is a schematic block diagram functionally illustrating an embodiment of a control unit 5 as discussed herein. As previously mentioned, the processor circuitry 6 may run software 21 for enabling the control unit to perform an embodiment of a method of the present disclosure, whereby functional modules may be formed in the control unit e.g. in the processor circuitry 6 for performing the different steps of the method. These modules are schematically illustrated as blocks within the control unit. Thus, the control unit comprises an obtaining constants module 51 for obtaining S21 constant values of coefficients b₁₋₅ and optional constant b₆ of a polynomial function describing said temperature difference ΔT. The control unit also comprises an obtaining parameters module 52 for obtaining S22 parameter values of variable physical parameters of said polynomial function, at least some of the parameter values being obtained by receiving sensor measurement signals. The control unit also comprises a calculating ΔT module 53 for calculating S23 the temperature difference ΔT by solving the polynomial function having the obtained constant values and the obtained parameter values. The control unit also comprises an outputting ΔT module for outputting S24 a signal comprising the calculated temperature difference ΔT to a controller 2 of the SMPS. As discussed above, the controller 2 may be comprised in the control unit 5 (e.g. if the control unit is comprised in the SMPS) or be separate from the control unit 5 (e.g. if the control unit is external to the SMPS).

According to an aspect of the present disclosure, there is provided a control unit 5 for determining a temperature difference ΔT between a real temperature T of a resistive element and a monitored temperature T_{MON} in an SMPS. The control unit comprises means 51 for obtaining S21 constant values of coefficients b₁₋₅ and optional constant b₆ of a polynomial function describing said temperature difference ΔT. The control unit also comprises means 52 for obtaining S22 parameter values of variable physical parameters of said polynomial function, at least some of the parameter values being obtained by receiving sensor measurement signals. The control unit also comprises means 53 for calculating S23 the temperature difference ΔT by solving the polynomial function having the obtained constant values and the obtained parameter values. The control unit also comprises means for outputting S24 a signal comprising the calculated temperature difference ΔT to a controller 2 of the SMPS.

In some embodiments of the present disclosure, the physical parameters discussed herein comprise any of input voltage V_{I} to the SMPS, output voltage V_{O} from the SMPS, output current I_{O} from the SMPS, airflow v past the SMPS and/or the monitored temperature T_{MON}. However, any other parameters which may affect ΔT may be included. Any number of physical parameters may be used, such as one, two or three physical parameters, but in order to obtain a polynomial function with sufficient accuracy for ΔT, it may be convenient to use at least three physical parameters with at least three respective coefficients b₁₋₃ which are not zero (since if a coefficient is zero, the physical parameter it relates to is irrelevant).

The present disclosure has mainly been described above with reference to a few embodiments. However, as is readily appreciated by a person skilled in the art, other embodiments than the ones disclosed above are equally possible within the scope of the present disclosure, as defined by the appended claims.

1-22. (canceled)

23. A method for estimating a current in a Switched-Mode Power Supply (SMPS), comprising:
receiving a first sensor signal including a value of a measured voltage over a resistive element in said SMPS;
receiving a second sensor signal including a value of a measured monitored temperature in said SMPS; and
calculating said current in said SMPS based on said measured voltage, said measured monitored temperature and a predetermined temperature difference between a temperature of said resistive element and said measured monitored temperature.

24. The method as recited in claim 23 wherein said calculating is performed in accordance with:
$${I}_{READ} = \frac{{V}_{ISENSE}}{GAIN ( 1 + TEMPCO ( {T}_{MON} - Δ T - 25 ) )} + OFFSET ,$$
wherein:
I_{READ} is said current in said SMPS,
V_{ISENSE} is said measured voltage,
GAIN is a gain value related to a resistance of said resistive element at 25 degrees Celsius,
T_{MON} is said measured monitored temperature,
TEMPCO is a temperature coefficient,
ΔT is said predetermined temperature difference, and
OFFSET is an offset due to a design of said SMPS.

25. The method as recited in claim 23 wherein said calculating is performed in accordance with:
$${I}_{READ \_ CORRECTED} = ( {I}_{READ} - OFFSET ) \cdot \frac{1 + TEMPCO ( {T}_{MON} - 25 )}{1 + TEMPCO ( {T}_{MON} - Δ T - 25 )} + OFFSET , \qquad$$
wherein:
I_{READ-CORRECTED} is a current in an external control unit to said SMPS,
I_{READ} is said current in said SMPS,
T_{MON} is said measured monitored temperature,
TEMPCO is a temperature coefficient,
ΔT is said predetermined temperature difference, and
OFFSET is an offset due to a design of said SMPS.

26. A control unit for estimating a current in a Switched-Mode Power Supply (SMPS), comprising:
processing circuitry operative to:
receive a first sensor signal including a value of a measured voltage over a resistive element in said SMPS;
receive a second sensor signal including a value of a measured monitored temperature in said SMPS; and
calculate said current in said SMPS based on said measured voltage, said measured monitored temperature and a predetermined temperature difference between a temperature of said resistive element and said measured monitored temperature.

27. The control unit as recited in claim 26 wherein said processing circuitry is operative to calculate said current in accordance with:
$${I}_{READ} = \frac{{V}_{ISENSE}}{GAIN ( 1 + TEMPCO ( {T}_{MON} - Δ T - 25 ) )} + OFFSET ,$$
wherein:
I_{READ} is said current in said SMPS,
V_{ISENSE} is said measured voltage,
GAIN is a gain value related to a resistance of said resistive element at 25 degrees Celsius,
T_{MON} is said measured monitored temperature,
TEMPCO is a temperature coefficient,
ΔT is said predetermined temperature difference, and
OFFSET is an offset due to a design of said SMPS.

28. The control unit as recited in claim 26 wherein said processing circuitry is operative to calculate said current in accordance with:
$${I}_{READ \_ CORRECTED} = ( {I}_{READ} - OFFSET ) \cdot \frac{1 + TEMPCO ( {T}_{MON} - 25 )}{1 + TEMPCO ( {T}_{MON} - Δ T - 25 )} + OFFSET , \qquad$$
wherein:
I_{READ-CORRECTED} is a current in an external control unit to said SMPS,
I_{READ} is said current in said SMPS,
T_{MON} is said measured monitored temperature,
TEMPCO is a temperature coefficient,
ΔT is said predetermined temperature difference, and
OFFSET is an offset due to a design of said SMPS.

29. A method performed by a control unit for determining a temperature difference between a temperature of a resistive element and a monitored temperature in a Switched-Mode Power Supply (SMPS), comprising:
obtaining constant values of coefficients and a constant of a function describing said temperature difference;
obtaining parameter values of physical parameters of said function; and
calculating said temperature difference by solving said function having said constant values of said coefficients and said parameter values.

30. The method as recited in claim 29 wherein said obtaining said constant values of said coefficients and said constant comprises retrieving said constant values of said coefficients and said constant from storage.

31. The method as recited in claim 29 wherein said obtaining said parameter values of said physical parameters comprises receiving sensor measurement signals including said parameter values of said physical parameters.

32. The method as recited in claim 29 further comprising outputting a signal including said temperature difference to a controller of said SMPS.

33. The method as recited in claim 29 wherein said function is a polynomial function.

34. The method as recited in claim 29 wherein said physical parameters are variable physical parameters.

35. The method as recited in claim 34 wherein said variable physical parameters comprise at least one of an input voltage to said SMPS, an output voltage from said SMPS, an output current from said SMPS, an airflow over said SMPS, and said monitored temperature.

36. A control unit for determining a temperature difference between a temperature of a resistive element and a monitored temperature in a Switched-Mode Power Supply (SMPS), comprising:
processing circuitry operative to:
obtain constant values of coefficients and a constant of a function describing said temperature difference;
obtain parameter values of physical parameters of said function; and
calculate said temperature difference by solving said function having said constant values of said coefficients and said parameter values.

37. The control unit as recited in claim 36 wherein said processing circuitry is operative to obtain said constant values of said coefficients and said constant from storage.

38. The control unit as recited in claim 36 wherein said processing circuitry is operative to obtain said parameter values of said physical parameters comprises receiving sensor measurement signals including said parameter values of said physical parameters.

39. The control unit as recited in claim 36 wherein said processing circuitry is operative to output a signal including said temperature difference to a controller of said SMPS.

40. The control unit as recited in claim 36 wherein said function is a polynomial function.

41. The control unit as recited in claim 36 wherein said physical parameters are variable physical parameters.

42. The control unit as recited in claim 41 wherein said variable physical parameters comprise at least one of an input voltage to said SMPS, an output voltage from said SMPS, an output current from said SMPS, an airflow over said SMPS, and said monitored temperature.
